(19) United States
(12) Patent Application Publication
(10) Pub. No.: US 2025/0157843 A1
(43) Pub. Date: May 15, 2025

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventor: Hiroyuki Kobayashi, Nagano (JP)

(21) Appl. No.: 18/940,314

(22) Filed: Nov. 7, 2024

(30) Foreign Application Priority Data
Nov. 9, 2023 (JP) 2023-191244

(51) Int. Cl. H01L 21/683; H01J 37/32

(52) U.S. Cl. CPC H01L 21/6833; H01J 37/32715; H01J 2237/334

(57) ABSTRACT

An electrostatic chuck includes a base body having a first surface and a second surface opposite to the first surface, a plurality of first electrodes and a plurality of second electrodes embedded in the base body, and a plurality of third electrodes exposed from the first surface and provided between the first electrodes and the second electrodes adjacent to each other in the base body. A plurality of protrusions are formed on the first surface. The third electrodes are provided at positions offset from the protrusions in a plan view perpendicular to the first surface.

### CROSS-REFERENCE TO RELATED APPLICATIONS

This application claims priority from Japanese Patent Application No. 2023-191244 filed on Nov. 9, 2023, the contents of which are incorporated herein by reference

### TECHNICAL FIELD

The present disclosure relates to an electrostatic chuck and a substrate fixing device.

### BACKGROUND ART

In the related art, a film formation apparatus and a plasma etching apparatus that are used when manufacturing a semiconductor device each have a stage for accurately holding a wafer in a vacuum treatment chamber. As such a stage, a substrate fixing device is suggested which adsorbs and holds a wafer using Coulombic force by an electrostatic chuck fixed on a base plate.

### CITATION LIST

### Patent Literature

PTL 1: JPH11-251416A
PTL 2: JP2023-006762A

### SUMMARY OF INVENTION

With repeated use, foreign matters may adhere to an adsorption surface of the electrostatic chuck. In addition, the foreign matters may become electrically charged. When the foreign matters become electrically charged, the foreign matters are adsorbed onto both the electrostatic chuck and the wafer. In addition, when removing the wafer from the electrostatic chuck, positional misalignment of the wafer may occur. Such positional misalignment may cause problems with subsequent wafer delivery and the like.

The present disclosure is to provide an electrostatic chuck and a substrate fixing device, which can easily remove charges electrically charged on foreign matters.

According to one aspect of the present disclosure, an electrostatic chuck includes a base body having a first surface and a second surface opposite to the first surface, a plurality of first electrodes and a plurality of second electrodes embedded in the base body, and a plurality of third electrodes exposed from the first surface and provided between the first electrodes and the second electrodes adjacent to each other. A plurality of protrusions are formed on the first surface. The third electrodes are provided at positions offset from the protrusions.

According to the present disclosure, it is possible to easily remove charges electrically charged on foreign matters.

### BRIEF DESCRIPTION OF DRAWINGS

FIG. 1 is a plan view illustrating a substrate fixing device according to a first embodiment.

FIG. 2 is a cross-sectional view illustrating the substrate fixing device according to the first embodiment.

FIG. 3 is a diagram illustrating a layout of positive electrodes, negative electrodes, a positive electrode connecting portion, and a negative electrode connecting portion of an electrostatic chuck.

FIG. 4 is a diagram illustrating a layout of the positive electrodes, the negative electrodes, and ground electrodes of the electrostatic chuck.

FIG. 5 is a cross-sectional view illustrating an electrostatic chuck of the substrate fixing device according to the first embodiment.

FIGS. 6A to 6C are cross-sectional views illustrating a method for manufacturing the electrostatic chuck of the substrate fixing device according to the first embodiment.

FIG. 7 is a cross-sectional view illustrating operational effects of the substrate fixing device according to the first embodiment.

FIG. 8 is a cross-sectional view illustrating an electrostatic chuck of a substrate fixing device according to a second embodiment.

FIG. 9 is a cross-sectional view illustrating an electrostatic chuck of a substrate fixing device according to a third embodiment.

FIG. 10 is a cross-sectional view illustrating an electrostatic chuck of a substrate fixing device according to a fourth embodiment.

FIG. 11 is a diagram illustrating a variation of the layout of the positive electrodes, negative electrodes, positive electrode connecting portion, and negative electrode connecting portion of the electrostatic chuck.

FIG. 12 is a diagram illustrating an outline of a test.

FIG. 13 is a diagram illustrating a test result.

FIG. 14 is a cross-sectional view illustrating an electrostatic chuck of a substrate fixing device according to a modified example of the third embodiment.

### DESCRIPTION OF EMBODIMENTS

Embodiments of the present disclosure will be described in detail below with reference to the accompanying drawings. Note that, in the specification and drawings, the constitutional elements having substantially the same functional configurations are denoted with the same reference signs, and the redundant descriptions may be omitted.

### First Embodiment

First of all, a first embodiment will be described. The first embodiment relates to a substrate fixing device.

### [Configuration of Substrate Fixing Device]

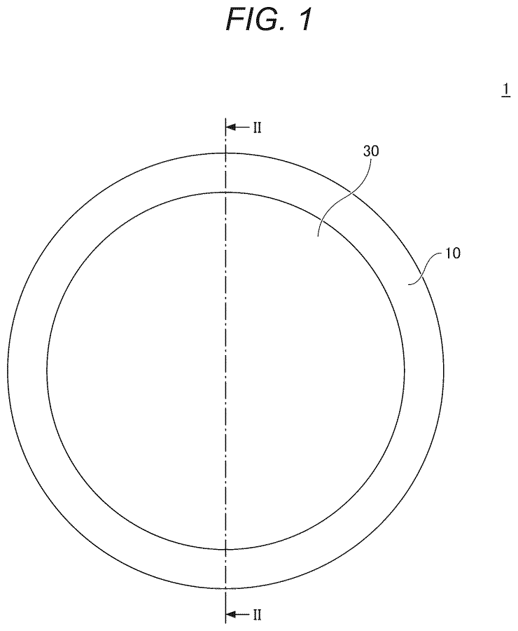

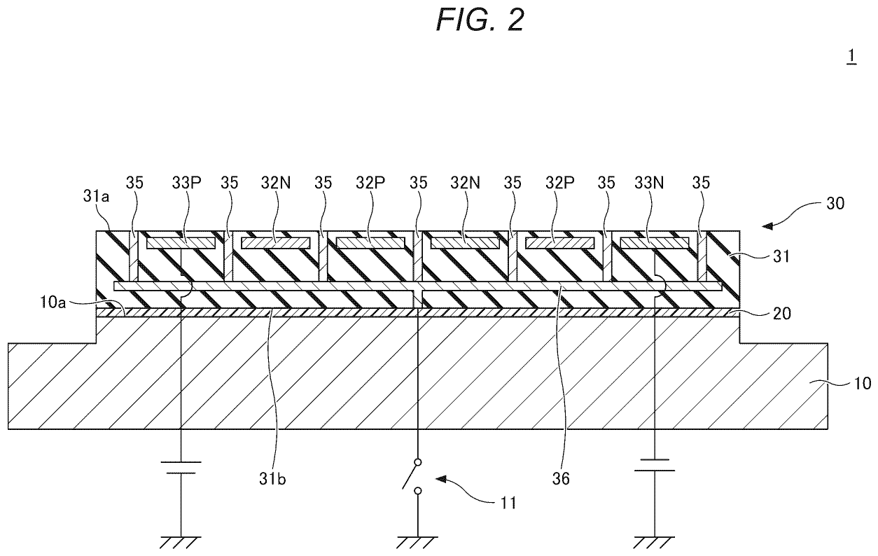

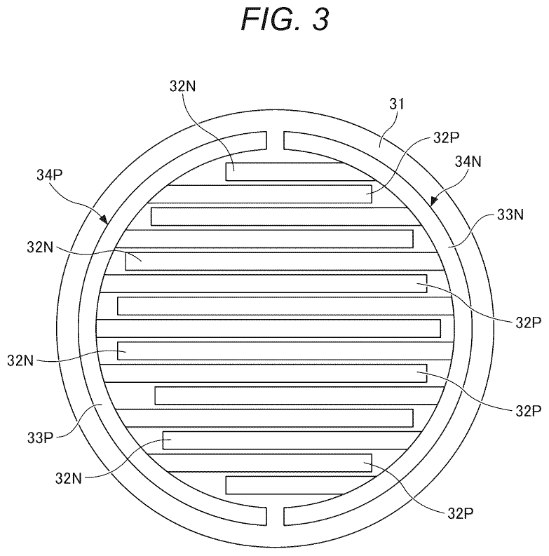

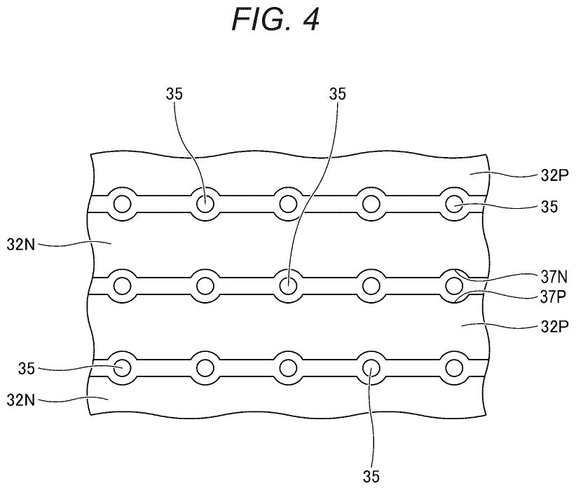

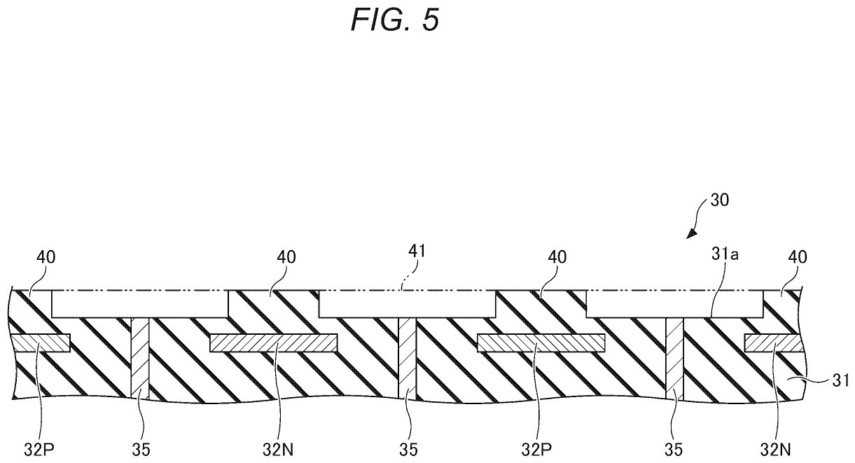

FIG. 1 is a plan view illustrating a substrate fixing device according to the first embodiment. FIG. 2 is a cross-sectional view illustrating the substrate fixing device according to the first embodiment. FIG. 3 is a diagram illustrating a layout of positive electrodes, negative electrodes, a positive electrode connecting portion, and a negative electrode connecting portion of an electrostatic chuck. FIG. 4 is a diagram illustrating a layout of the positive electrodes, the negative electrodes, and ground electrodes of the electrostatic chuck. FIG. 5 is a cross-sectional view illustrating an electrostatic chuck of the substrate fixing device according to the first embodiment. FIG. 2 corresponds to a cross-sectional view taken along line II-II in FIG. 1.

As shown in FIGS. 1 and 2, a substrate fixing device 1 according to the first embodiment includes, main constitutional elements, a base plate 10, an adhesive layer 20, and an electrostatic chuck 30. The substrate fixing device 1 is a device that adsorbs and holds an object such as a substrate (a wafer or the like), which is a target object to be adsorbed, by the electrostatic chuck 30 fixed on one surface 10a of the base plate 10.

Note that, in the present disclosure, it is assumed that the description ‘in a plan view’ indicates that a target object is seen from a normal direction of the surface 10a of the base plate 10, and the description ‘planar shape’ indicates a shape of the target object as seen from the normal direction of the surface 10a of the base plate 10.

The base plate 10 is a member for mounting the electrostatic chuck 30. A thickness of the base plate 10 is, for example, about 20 mm to 40 mm. The base plate 10 is formed of, for example, aluminum, and can be used as an electrode or the like for controlling plasma. By supplying predetermined high-frequency electric power to the base plate 10, the energy for causing ions and the like in a generated plasma state to collide with the substrate adsorbed on the electrostatic chuck 30 can be controlled to effectively perform etching processing.

The electrostatic chuck 30 is a part that adsorbs and holds a wafer, which is a target object to be adsorbed. A planar shape of the electrostatic chuck 30 is circular, for example. A diameter of the wafer, which is a target object to be adsorbed of the electrostatic chuck 30, is, for example, 8 inches, 12 inches, or 18 inches.

The electrostatic chuck 30 is provided on one surface 10a of the base plate 10 via the adhesive layer 20. The electrostatic chuck 30 includes a base body 31, a plurality of positive electrodes 32P, a plurality of negative electrodes 32N, a positive electrode connecting portion 33P, a negative electrode connecting portion 33N, a plurality of ground electrodes 35, and a ground wiring 36. A material of the adhesive layer 20 is, for example, a silicone-based adhesive. A thickness of the adhesive layer 20 is, for example, about 0.1 mm to 1.5 mm. The adhesive layer 20 bonds the base plate 10 and the electrostatic chuck 30, and has an effect of reducing stress generated due to a difference in thermal expansion coefficient between the electrostatic chuck 30 made of ceramic and the base plate 10 made of aluminum.

The base body 31 is a dielectric body. As the base body 31, for example, ceramic such as aluminum oxide (Al₂O₃) or aluminum nitride (AlN) is used. A thickness of the base body 31 is, for example, about 1 mm to 6 mm, and a relative permittivity (kHz) of the base body 31 is, for example, about 9 to 10. The base body 31 has a first surface 31a and a second surface 31b opposite to the first surface 31a. The first surface 31a is a surface on which an object, which is a target object to be absorbed, is placed.

As shown in FIG. 5, a plurality of protrusions 40 are formed on the first surface 31a of the base body 31. Heights of respective tops of the plurality of protrusions 40 relative to the surface 10a are substantially the same, and the tops of the plurality of protrusions 40 are in one virtual plane 41. The top of the protrusion 40 is, for example, a flat surface. An object, which is a target object to be absorbed, is placed on the top of the protrusion 40. Note that, in FIG. 2, the protrusions 40 are omitted.

The positive electrode 32P, the negative electrode 32N, the positive electrode connecting portion 33P, and the negative electrode connecting portion 33N are formed by a thin film and embedded in the base body 31. As shown in FIGS. 3 and 4, the positive electrode 32P and the negative electrode 32N have a substantially rectangular planar shape, and their respective long sides are parallel to each other. Additionally, the positive electrodes 32P and the negative electrodes 32N are arranged alternately in a width direction. Examples of materials of the positive electrode 32P, the negative electrode 32N, the positive electrode connecting portion 33P, and the negative electrode connecting portion 33N include tungsten and molybdenum.

One end portion of each of the plurality of positive electrodes 32P is connected to the positive electrode connecting portion 33P. The plurality of positive electrodes 32P are electrically connected to the positive electrode connecting portion 33P and electrically insulated from the negative electrode connecting portion 33N. One end portion of each of the plurality of negative electrodes 32N is connected to the negative electrode connecting portion 33N. The plurality of negative electrodes 32N are electrically connected to the negative electrode connecting portion 33N and electrically insulated from the positive electrode connecting portion 33P. For example, a positive-side conductive film 34P, which is formed by integrating the plurality of positive electrodes 32P and the positive electrode connection portions 33P, is shaped in a comb-like electrode pattern, and a negative-side conductive film 34N, which is formed by integrating the plurality of negative electrodes 32N and the negative electrode connection portions 33N, is shaped in a comb-like electrode pattern.

The positive electrode connecting portion 33P and the negative electrode connecting portion 33N are connected to a power supply provided outside the substrate fixing device 1. When a predetermined voltage is applied from the power supply to the positive electrode connecting portion 33P and the negative electrode connecting portion 33N, an uneven electric field is generated between the positive electrode 32P and the negative electrode 32N adjacent to each other, and a gradient force is generated due to the uneven electric field. The gradient force makes it possible to adsorb and hold an object such as a wafer on the first surface 31a of the base body 31 of the electrostatic chuck 30. The positive electrode 32P is an example of a first electrode, and the negative electrode 32N is an example of a second electrode.

As shown in FIG. 2, the base plate 10, the adhesive layer 20, and the base body 31 are provided with a voltage supply path for applying a positive (+) voltage to the positive electrode connecting portion 33P and a negative (−) voltage to the negative electrode connecting portion 33N.

As shown in FIG. 4, each of the plurality of ground electrodes 35 is provided between the positive electrode 32P and the negative electrode 32N adjacent to each other. The ground electrode 35 has a pillar shape. The ground electrode 35 may have a cylinder shape. Examples of a material of the ground electrode 35 include tungsten and molybdenum.

As shown in FIG. 5, the ground electrode 35 is exposed from the first surface 31a of the base body 31. The ground electrode 35 extends along the normal direction of the surface 10a. That is, the ground electrode 35 extends to be orthogonal to the positive electrode 32P and the negative electrode 32N. The ground electrode 35 has an end portion on the first surface 31a side and an end portion on the second surface 31b side. The end portion on the first surface 31a side may be flush with the first surface 31a. The entire ground electrode 35 is located on the second surface 31b side with respect to the virtual plane 41. That is, a distance between a portion of the ground electrode 35 farthest from the second surface 31b and the second surface 31b is smaller than a distance between the virtual plane 41 and the second surface 31b. In addition, as shown in FIG. 2, the ground wiring 36 is connected to each end portion on the second surface 31b side. A switch 11 for switching conduction and non-conduction states between the ground wiring 36 and the ground is provided outside the base plate 10. The ground electrode 35 is an example of a third electrode.

In a plan view, the ground electrode 35 is provided at a position offset from the protrusion 40. For example, the ground electrode 35 is provided between the adjacent protrusions 40. The ground electrode 35 may be provided at a center between the adjacent protrusions 40. The ground electrodes 35 may be provided at grid points of a square grid. That is, the ground electrodes 35 may be provided at a certain pitch in a first direction perpendicular to the normal direction of the surface 10a and in a second direction perpendicular to the normal direction of the surface 10a and the first direction. In a plan view, a distance between the adjacent ground electrodes 35 is preferably 80 mm or less, more preferably 30 mm or less, and even more preferably 20 mm or less. In the case where the distance between the ground electrodes 35 is 20 mm or less, when a diameter of the first surface 31a is 12 inches, a total of 170 or more ground electrodes 35 are included in the electrostatic chuck 30.

As shown in FIG. 4, concave portions 37P and 37N may be formed on surfaces, which face each other while sandwiching the ground electrode 35, of the positive electrode 32P and the negative electrode 32N so as to be spaced apart from the ground electrodes 35 in a plan view. In this case, the concave portion 37P is formed on the positive electrode 32P, and the concave portion 37N is formed on the negative electrode 32N.

A heating element (heater) that generates heat when a voltage is applied from the outside of the substrate fixing device 1 and heats the first surface 31a of the base body 31 to a predetermined temperature may also be provided in the base body 31.

### [Method for Manufacturing Electrostatic Chuck]

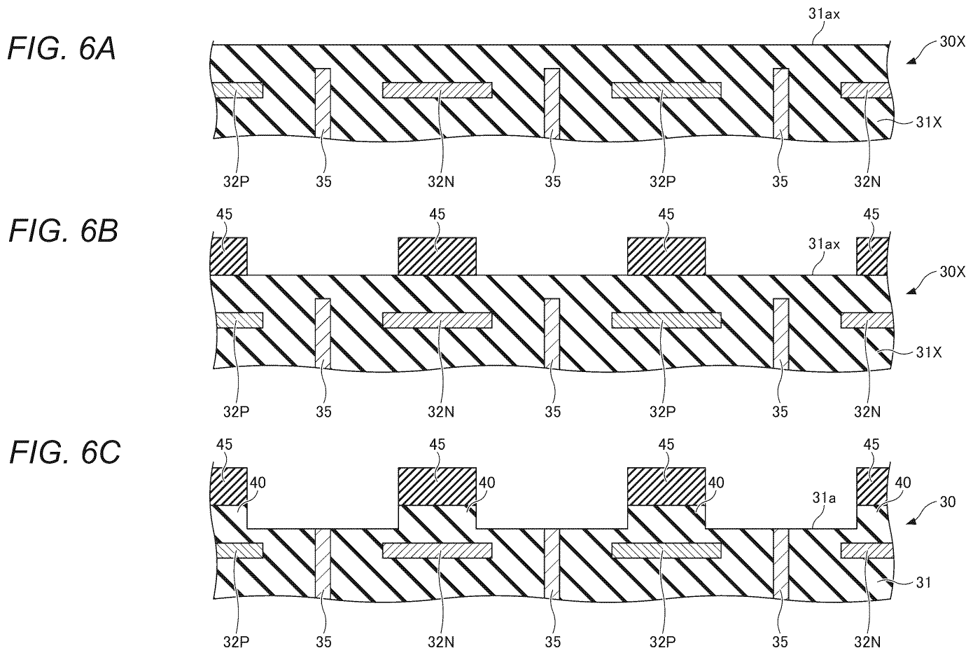

Next, a method for manufacturing the electrostatic chuck 30 will be described. FIGS. 6A to 6C are cross-sectional views illustrating a method for manufacturing the electrostatic chuck of the substrate fixing device according to the first embodiment.

First, a composite body 30X is formed by, for example, co-firing of a green sheet and a conductive paste, as shown in FIG. 6A. The composite body 30X is a composite body in which a base body 31X, on which no protrusion 40 is formed, positive electrodes 32P, negative electrodes 32N, a positive electrode connecting portion 33P, a negative electrode connecting portion 33N, ground electrodes 35, and a ground wiring 36 are integrated. The base body 31X has a surface 31ax on which no protrusion 40 is formed. A first surface 31a is formed from the surface 31ax. In the composite body 30X, the ground electrodes 35 are embedded in the base body 31X. An end portion, on the surface 31ax side, of the ground electrode 35 is covered by the base body 31X.

Next, as shown in FIG. 6B, a mask 45 is formed which covers portions to form protrusions 40 of the base body 31X. The mask 45 is formed so as not to overlap the ground electrodes 35 in a plan view.

Next, as shown in FIG. 6C, portions, which are exposed from the mask 45, of the base body 31X are removed by blast processing using silicon carbide particles or the like until the ground electrodes 35 are exposed. As a result, protrusions 40 are formed on the portions of the base body 31X covered by the mask 45, a first surface 31a is formed from the surface 31ax, and a base body 31 is formed from the base body 31X. The mask 45 is then removed.

In this way, the electrostatic chuck 30 can be manufactured.

When manufacturing a substrate fixing device 1, a separate base plate 10 is prepared, the base plate 10 and the electrostatic chuck 30 are bonded together using an uncured adhesive, and the adhesive is cured to form an adhesive layer 20. In this way, the substrate fixing device 1 according to the first embodiment can be manufactured.

### [Operational Effects of Substrate Fixing Device]

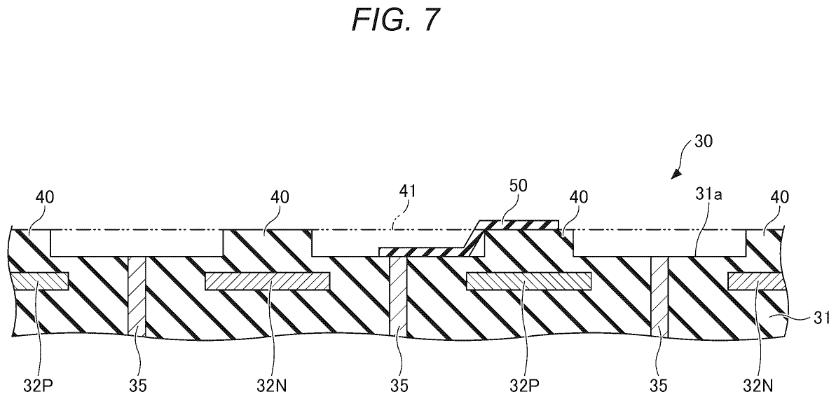

Next, operational effects of the substrate fixing device 1 according to the first embodiment will be described. FIG. 7 is a cross-sectional view illustrating operational effects of the substrate fixing device according to the first embodiment.

In the substrate fixing device 1, with repeated use, foreign matters 50 may adhere to the first surface 31a of the base body 31. The electrical charging of the foreign matters 50 increases with each wafer adsorption, and the increase in electrical charging induces further attachment of foreign matters, leading to an increase in an amount of electrical charge. The increased electrical charging remains even after the wafer adsorption is released, making it difficult to separate the wafer from the electrostatic chuck. In the present embodiment, even when charges remain on the foreign matters 50 due to the electrical charging, the charges on the foreign matters 50 are eliminated because the ground electrodes 35 are grounded by switching the switch 11 (see FIG. 2) to the conduction state. As a result, the charges electrically charged on the foreign matters 50 can be easily removed. When adsorbing a target object to be adsorbed such as a wafer, the switch 11 is switched to the non-conduction state.

In addition, although the positions where the foreign matters 50 are attached are not constant, by providing the plurality of ground electrodes 35, the charges can be eliminated from the foreign matters 50 either by coming into contact with the ground electrodes 35 or through the ground electrodes 35, regardless of the positions of the foreign matters 50. In addition, since the electrostatic chuck 30 adsorbs an object by the gradient force, and the ground electrode 35 is provided between the positive electrode 32P and the negative electrode 32N, a reduction in an area, in a plan view, of the positive electrode 32P and the negative electrode 32N compared to a case where the ground electrode 35 is not provided is small, and sufficient adsorption force can be obtained. In particular, the electrostatic chuck 30 is suitable for adsorption of a semiconductor substrate such as a silicon substrate.

In addition, since the entire ground electrode 35 is located on the second surface 31b side with respect to the virtual plane 41, it is difficult for the ground electrode 35 to come into contact with a target object to be adsorbed such as a wafer. If the ground electrode 35 comes into contact with a target object to be adsorbed, there is a concern that metal atoms included in the ground electrode 35 may be mixed into the target object to be adsorbed. However, when such contact does not occur, mixing and the like can be prevented.

In addition, the charges can be eliminated not only from the foreign matters 50 but also from the target object to be adsorbed, such as a wafer. In addition, the effect of eliminating the charges can prevent the induction of foreign matter attachment.

### Second Embodiment

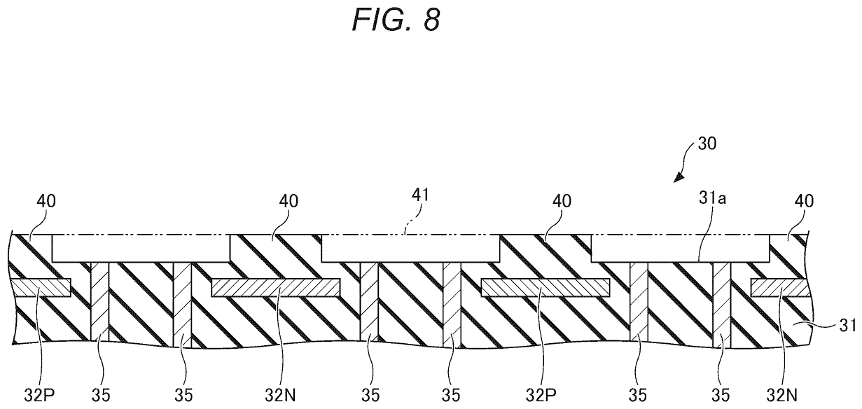

Next, a second embodiment will be described. The second embodiment is mainly different from the first embodiment, in terms of arrangement of the ground electrodes. FIG. 8 is a cross-sectional view illustrating an electrostatic chuck of a substrate fixing device according to the second embodiment.

As shown in FIG. 8, in the second embodiment, a plurality of, for example two, ground electrodes 35 are provided between the adjacent protrusions 40. In addition, the distance between the ground electrode 35 and the protrusion 40 is shorter than in the first embodiment.

Other configurations of the second embodiment are similar to those of the first embodiment.

According to the second embodiment, the similar effects to those of the first embodiment can be obtained. In addition, according to the second embodiment, the more ground electrodes 35 are provided, making it easier to eliminate the charges when the foreign matters 50 are attached. Furthermore, even when the foreign matters 50 are attached to the protrusion 40, it is easier to eliminate the charges because the distance between the ground electrode 35 and the protrusion 40 is shorter.

### Third Embodiment

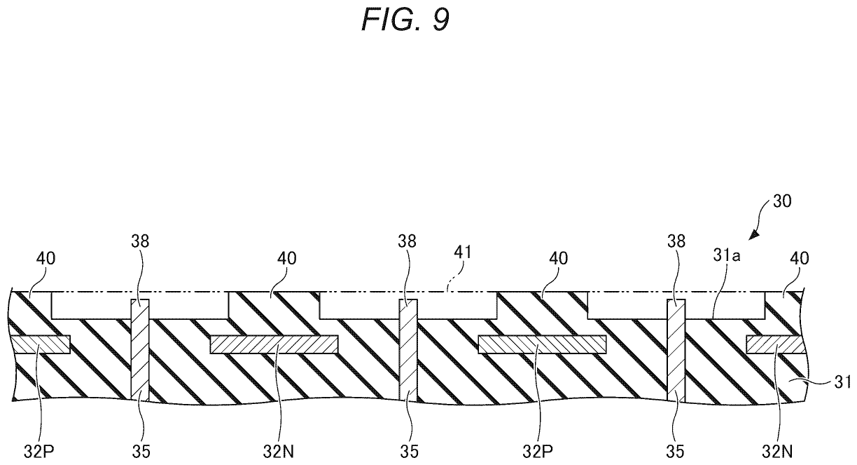

Next, a third embodiment will be described. The third embodiment is mainly different from the first embodiment, in terms of the size of the ground electrode. FIG. 9 is a cross-sectional view illustrating an electrostatic chuck of a substrate fixing device according to the third embodiment.

As shown in FIG. 9, in the third embodiment, the ground electrode 35 has a protruding portion 38 protruding from the first surface 31a. However, as in the first embodiment, the entire ground electrode 35 including the protruding portion 38 is located on the second surface 31b side with respect to the virtual plane 41.

Other configurations of the third embodiment are similar to those of the first embodiment.

According to the third embodiment, the similar effects to those of the first embodiment can be obtained. In addition, according to the third embodiment, since the ground electrode 35 has the protruding portion 38, the distance between the ground electrode 35 and the target object to be adsorbed, such as a wafer, is shorter, making it easier to eliminate the charges from the target object to be adsorbed.

Note that a height of the protruding portion 38 can be adjusted, for example, in accordance with a diameter of the protruding portion 38. When manufacturing the electrostatic chuck 30, blast processing is performed as described above. The ground electrode 35 made of metal can also be thinned by blast processing. For this reason, depending on the diameter of the protruding portion 38, the height may become smaller along with the thinning. For example, the composite body 30X may be formed such that one end of the ground electrode 35 reaches the surface 31ax of the base body 31X (see FIG. 6A), and the ground electrode 35 may be cut to such an extent that the protruding portion 38 remains during blast processing.

### Fourth Embodiment

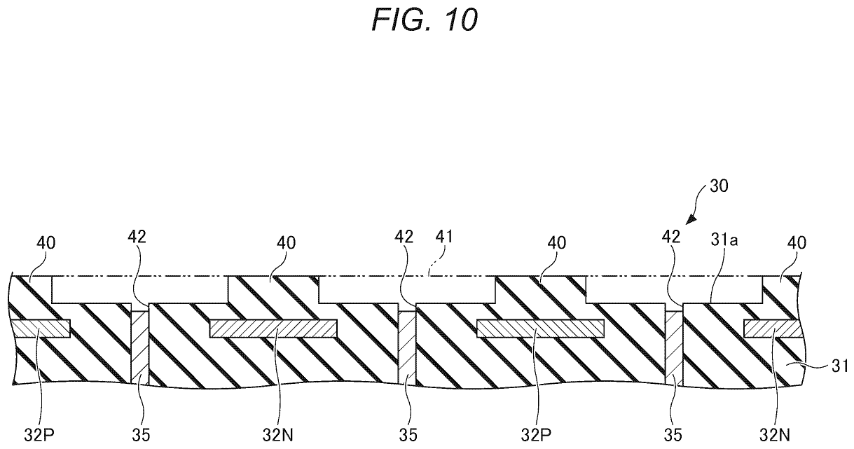

Next, a fourth embodiment will be described. The fourth embodiment is mainly different from the first embodiment, in terms of the size of the ground electrode. FIG. 10 is a cross-sectional view illustrating an electrostatic chuck of a substrate fixing device according to the fourth embodiment.

As shown in FIG. 10, in the fourth embodiment, the entire ground electrode 35 is located on the second surface 31b side with respect to the first surface 31a, and an opening portion 42 through which the ground electrode 35 is exposed is formed in the first surface 31a. That is, the distance between the portion of the ground electrode 35 farthest from the second surface 31b and the second surface 31b is smaller than the shortest distance between the first surface 31a and the second surface 31b.

Other configurations of the fourth embodiment are similar to those of the first embodiment.

According to the fourth embodiment, the similar effects to those of the first embodiment can be obtained. In addition, according to the fourth embodiment, since the entire ground electrode 35 is located on the second surface 31b side with respect to the first surface 31a, even when the target object to be adsorbed comes into contact with the bottom of the concave portion between the protrusions 40, it is possible to avoid contact between the ground electrode 35 and the target object to be adsorbed.

Note that the opening portion 42 can be formed by including a material that is easy to polish, such as alumina, in the metal paste used to form the ground electrode 35 when manufacturing the electrostatic chuck 30. For example, in the composite body 30X (see FIG. 6A), when the size of the ground electrode 35 is made similar to that of the first embodiment and a material that is easy to polish is included in the ground electrode 35, the ground electrode 35 is slightly cut during blast processing, allowing the opening portion 42 to be formed.

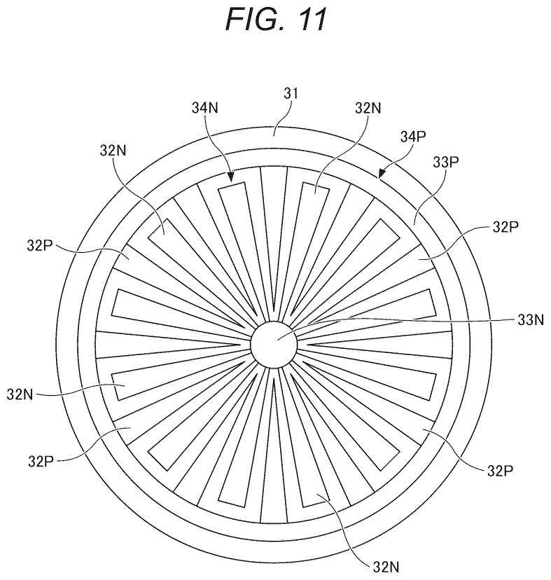

Note that as long as the positive electrodes 32P and the negative electrodes 32N are arranged in a way that enables the gradient force to be obtained, the positive electrodes 32P and the negative electrodes 32N need not be arranged alternately on the straight lines. For example, as shown in FIG. 11, the positive electrodes 32P and the negative electrodes 32N may be alternately arranged on a circumstance. In this case, for example, the negative electrode connecting portion 33N is arranged at a center of the circumstance, the annular positive electrode connecting portion 33P is arranged on an outer side of the positive electrodes 32P and the negative electrodes 32N, the plurality of positive electrodes 32P are electrically connected to the positive electrode connecting portion 33P, and the plurality of negative electrodes 32N are electrically connected to the negative electrode connecting portion 33N.

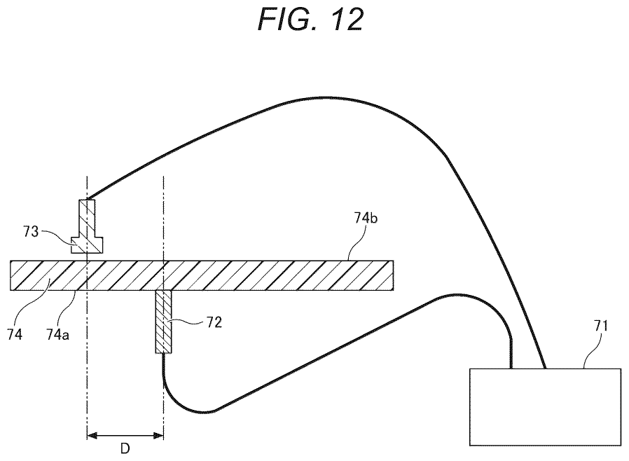

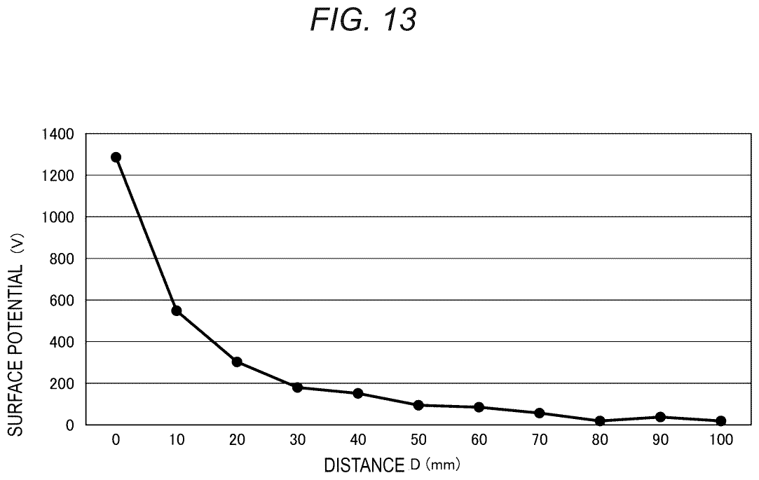

Here, the test conducted by the inventor of the present invention with respect to the spacing between the ground electrodes 35 will be described. FIG. 12 is a diagram illustrating an outline of a test. FIG. 13 is a diagram illustrating a test result.

In this test, as shown in FIG. 12, a reference electrode 72, which was supplied with a ground potential and a probe 73, were connected to a surface electrometer 71, the reference electrode 72 was brought into contact with one surface 74a of an acrylic plate 74 electrically charged in a simple way, and the probe 73 was brought close to the other surface 74b. Then, the surface potential of the surface 74b was measured by the probe 73 while changing a distance D between the reference electrode 72 and the probe 73 in a direction parallel to the surfaces 74a and 74b. A result thereof is shown in FIG. 13.

As shown in FIG. 13, when the distance D was 80 mm or less, the difference in surface potential due to the difference in the distance D was significant. When the distance D was 30 mm or less, the difference in surface potential was more significant, and when the distance D was 20 mm or less, the difference in surface potential was even more significant. From this result, the distance between the adjacent ground electrodes 35 in a plan view is preferably 80 mm or less, more preferably 30 mm or less, and even more preferably 20 mm or less.

Although the preferred embodiments have been described in detail, the present disclosure is not limited to the above-described embodiments, and a variety of changes and replacements can be made for the above-described embodiments without departing from the scope defined in the claims.

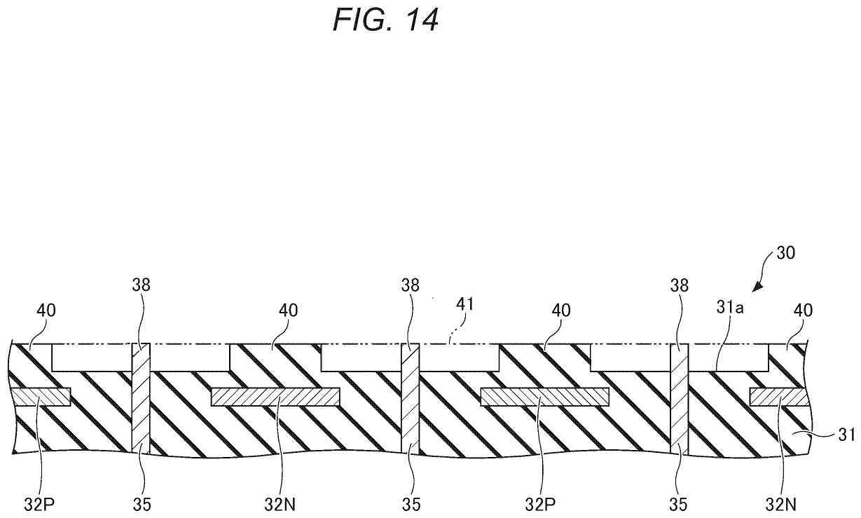

In the third embodiment, an end portion of the protruding portion 38 of the ground electrode 35 is located on the first surface side with respect to the virtual plane. However, as shown in FIG. 14, an end portion of the protruding portion 38 of the ground electrode 35 may be flush with the virtual plane 41. According to this embodiment, the similar effects to those of the third embodiment can be obtained.

What is claimed is:

1. An electrostatic chuck comprising:
a base body having a first surface and a second surface opposite to the first surface;
a plurality of first electrodes and a plurality of second electrodes for absorbing an object on the first surface, the plurality of first electrodes and the plurality of second electrodes embedded in the base body; and
a plurality of third electrodes exposed from the first surface and provided between the first electrodes and the second electrodes adjacent to each other in the base body,
wherein a plurality of protrusions are formed on the first surface, and
wherein the third electrodes are provided at positions offset from the protrusions in a plan view perpendicular to the first surface.

2. The electrostatic chuck according to claim 1, wherein tops of the plurality of protrusions are in one virtual plane, and
wherein the entire third electrodes are located on the second surface side with respect to the virtual plane.

3. The electrostatic chuck according to claim 2, wherein each of the third electrodes has a protruding portion protruding from the first surface.

4. The electrostatic chuck according to claim 1, wherein the entire third electrodes are located on the second surface side with respect to the first surface, and
wherein opening portions through which the third electrodes are exposed are formed in the first surface.

5. The electrostatic chuck according to claim 1, wherein a distance between the third electrodes adjacent to each other is 80 mm or less, in the plan view perpendicular to the first surface.

6. The electrostatic chuck according to claim 1, further comprising:
a wiring connected to the plurality of third electrodes and capable of being grounded.

7. A substrate fixing device comprising:
a base plate; and
an electrostatic chuck fixed to the base plate,
wherein the electrostatic chuck comprises:
a base body having a first surface and a second surface opposite to the first surface;
a plurality of first electrodes and a plurality of second electrodes for absorbing an object on the first surface, the plurality of first electrodes and the plurality of second electrodes embedded in the base body; and
a plurality of third electrodes exposed from the first surface and provided between the first electrodes and the second electrodes adjacent to each other in the base body,
wherein a plurality of protrusions are formed on the first surface, and
wherein the third electrodes are provided at positions offset from the protrusions in a plan view perpendicular to the first surface.

8. The electrostatic chuck according to claim 3, wherein an end portion of the protrusion of the third electrode is flush with the virtual plane or is located on the first surface side with respect to the virtual plane.
